(19) United States
(12) Patent Application Publication
(10) Pub. No.: US 2024/0057280 A1
(43) Pub. Date: Feb. 15, 2024

(54) SERVER

(71) Applicant: Beijing Tusen Zhitu Technology Co., Ltd., Beijing (CN)

(72) Inventors: Zhihua MA, Beijing (CN); Haiquan LI, Beijing (CN)

(21) Appl. No.: 18/446,389

(22) Filed: Aug. 8, 2023

(30) Foreign Application Priority Data
Aug. 11, 2022 (CN) 202222115214.6

(51) Int. Cl. H05K 7/14; H05K 7/20; H05K 5/02

(52) U.S. Cl. CPC H05K 7/1491; H05K 7/20154; H05K 7/20172; H05K 5/0247; H05K 5/0286

(57) ABSTRACT

A server includes a housing, a partition, and a network interface card module. The housing forms an interior space, and the partition divides the interior space into a first space and a second space. The network interface card module includes a network interface card, a slot body, and a network cable. The network interface card is located in the first space. An opening of the partition accommodates the slot body. The slot body includes a recess and a first space opening, and the recess is recessed toward the first space to form a recess space. The network cable is connected to the network interface card, and the network cable sequentially passes through the first space opening and the recess space to enter the second space. The network interface card module of the server can realize the heat dissipation and dustproof effects for the network interface card.

The present application claims priority to and the benefit of Chinese Patent Application No. 202222115214.6, filed on Aug. 11, 2022. The aforementioned application is incorporated by reference hereinin its entirety.

### TECHNICAL FIELD

The present document relates to a server and, more particularly, to an in-vehicle server.

### BACKGROUND

Generally, an in-vehicle server for decision-making and control is provided on an autonomous vehicle for the need of automatic driving.

### SUMMARY

The present document provides a server capable of achieving successful installation of a network interface card while having a structure suitable for an in-vehicle environment.

In an aspect of the present document, a server is provided, including:
a housing forming an interior space;
a partition dividing the interior space into a first space and a second space, the partition including an opening; and
a network interface card module, including:
a network interface card located in the first space;
a slot body accommodated by the opening, including:
a recess, recessed toward the first space to form a recess space; and
a first space opening communicating the first space and the recess space; and
a network cable connected to the network interface card, the network cable sequentially passing through the first space opening and the recess space to enter the second space.

According to the above-mentioned document, the network cable is connected to the network interface card in the first space of the server's housing, and the network cable passes through the first space opening and the recess space of the slot body in sequence so as to enter the second space of the server's housing; as a result, even if the network interface card is configured in the first space, the majority of the network cable may be configured in the second space through the slot body, not necessarily configured in the first space together with the network interface card. Therefore, the network interface card may be successfully installed, and adaptation to the server structure design in an in-vehicle environment is realized.

### BRIEF DESCRIPTION OF THE DRAWINGS

The accompanying drawings, which are incorporated in and constitute a part of this specification, illustrate embodiments and, together with the description, serve to explain exemplary embodiments of the embodiments. It is apparent that the drawings in the following description are only some rather than all embodiments of the present document, and for a person skilled in the art, other drawings can be obtained according to these drawings without involving any inventive effort. Throughout the drawings, the same reference numerals indicate similar, but not necessarily identical, elements.

FIGS. 1 to 6 are structural diagrams of a server in a process of assembling according to some embodiments of the present document (some elements are not shown);

FIG. 7 is an exploded view of a server according to some embodiments of the present document.

FIG. 8 is an exploded view of a network interface card module and related elements thereof according to some embodiments of the present document.

FIGS. 9 to 12 are structural diagrams of the network interface card module and related elements thereof in the process of mounting according to some embodiments of the present document.

### DETAILED DESCRIPTION

In order that those skilled in the art better understand the technical solution of the present document, the technical solution of the embodiments of the present document will be clearly and completely described below with reference to the accompanying drawings of the embodiments of the present document. It is apparent that the described embodiments are only some rather than all embodiments of the present document. Based on the embodiments of the present document, all the other embodiments obtained by those of ordinary skill in the art without involving any inventive effort shall fall within the scope of the present document.

In the present document, the term “plurality” means two or more, unless otherwise specified. In the present document, unless otherwise noted, the use of the terms “first”, “second”, and the like is intended to distinguish between similar objects and is not intended to limit their positional, temporal, or importance relationships. It is to be understood that the terms so used are interchangeable under appropriate circumstances such that the embodiments of the present document described herein are capable of operation in other ways than those illustrated or otherwise described herein.

Generally, an in-vehicle server for decision-making and control is provided on an autonomous vehicle for the need of automatic driving. In-vehicle servers may face different challenges than general servers. The technology involved in automatic driving is complicated, and an in-vehicle server needs to have high processing efficiency and networking performance, hence a processor with high computational efficiency and a proper network interface card may be employed. In addition, to avoid damage to boards or elements due to vibration in an in-vehicle environment, a corresponding support board is provided inside the server's housing to improve structural strength. Proper heat sink structures are also provided inside the server's housing to facilitate heat dissipation and dust prevention for the network interface card, so as to ensure the efficient and stable operation of the network interface card of the in-vehicle server. However, structures like the support board inside the server's housing limit the interior space of the server's housing, and the arrangement of the network cable of the network interface card is limited, leading to poor applicability.

It is a technical problem to be solved urgently by those skilled in the art as to how to configure an appropriate server structure to adapt to an in-vehicle environment and achieve successful installation of a network interface card.

The server provided in the embodiments of the present document can be applied to a vehicle with an automatic driving function or a vehicle with an auxiliary driving function and can also be applied to a vehicle configured to allow manual driving. The present application does not strictly define the application scenario.

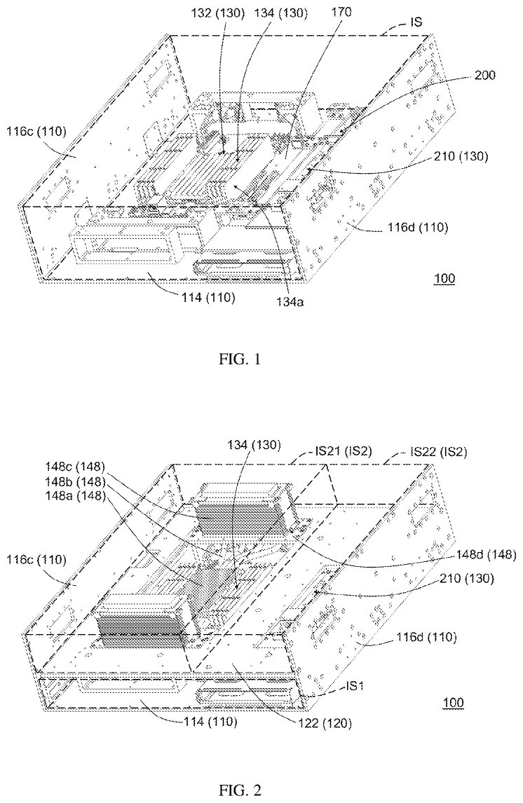

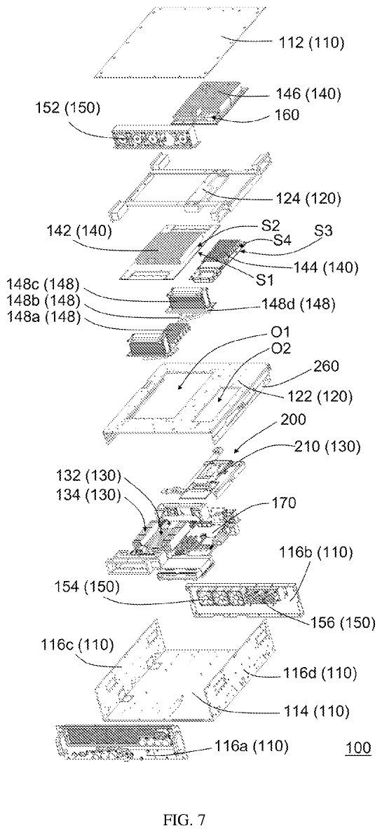

FIGS. 1 to 6 depict a process of assembling the server 100 according to some embodiments of the present document. FIG. 7 is an exploded view of the server 100. At least some of FIGS. 1 to 6 and FIG. 7 illustrate an interior structure of the server 100 and the relationship among various elements of the server 100.

Referring to FIGS. 1 and 5 to 7, in the embodiments, the server 100 includes a housing 110. The housing 110 includes, for example, an upper board 112, a lower board 114, and a plurality of sidewalls. These sidewalls include a first sidewall 116a, a second sidewall 116b, a third sidewall 116c, and a fourth sidewall 116d. The first sidewall 116a is opposite the second sidewall 116b, and the third sidewall 116c is opposite the fourth sidewall 116d. The second sidewall 116b is located on a side opposite the first sidewall 116a, and the fourth sidewall 116d is located on a side opposite the third sidewall 116c. The first sidewall 116a is, for example, a front panel of the server 100, and the second sidewall 116b is, for example, a back panel located opposite the front panel. Further, the third sidewall 116c, the lower board 114, and the fourth sidewall 116d form a U-shaped board structure. However, these sidewalls may also be provided with other structures or functions according to actual requirements, and the present document is not limited thereto.

In the embodiments, the housing 110 forms an interior space IS. The interior space IS is, for example, a space surrounded by the upper board 112, the lower board 114, and the plurality of sidewalls connecting the upper board 112 and the lower board 114, including the first sidewall 116a, the second sidewall 116b, the third sidewall 116c, and the fourth sidewall 116d. The server 100 further includes a support module 120 located in the interior space IS. The support module 120 includes a partition 122 having an opening between the upper board 112 and the lower board 114. The partition 122 divides the interior space IS into a first space IS1 and a second space IS2. The first space IS1 is located below, i.e., on the side of the lower board 114, and the second space IS2 is located above, i.e., on the side of the upper board 112. Specifically, the lower board 114, the first sidewall 116a, the second sidewall 116b, the third sidewall 116c, the fourth sidewall 116d, and the partition 122 form the first space IS1, and the upper board 112, the first sidewall 116a, the second sidewall 116b, the third sidewall 116c, the fourth sidewall 116d, and the partition 122 form the second space IS2.

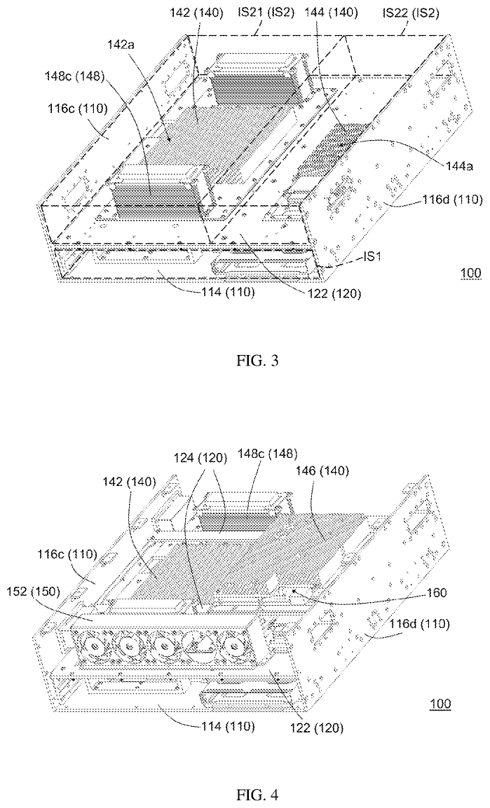

Furthermore, the server 100 further includes a heat-generating element set 130, a heat dissipating unit 140, and a main board 170. The main board 170 and the heat-generating element set 130 are located in the first space IS1, and the heat-generating element set 130 includes a central processing unit (CPU) 132 and a memory module 134. The main board 170 is located on the lower board 114, and the CPU 132 and the memory module 134 are mounted on the main board 170. The heat dissipating unit 140 includes a first heat sink 142. Referring to FIG. 3, the first heat sink 142 has a heat dissipating structure, i.e., a first heat dissipating structure 142a, to dissipate heat from the heat-generating element set 130 in the first space IS1.

In the embodiments, the first heat sink 142 and the support module 120 divide the interior space IS into the first space IS1 and the second space IS2. Specifically, a first opening O1 of the partition 122 accommodates the first heat sink 142. When the first heat sink 142 is mounted into the first opening O1, the lower board 114, the plurality of sidewalls, the partition 122, and the first heat sink 142 form the first space IS1. The first space IS1 is, for example, a closed space.

Referring to FIGS. 3 and 7, the first heat sink 142 has a first surface S1 facing the first space IS1 and a second surface S2 facing the second space IS2, and the second surface S2 of the first heat sink 142 has a first heat dissipating structure 142a. Further, the first surface S1 of the first heat sink 142 contacts the heat-generating element set 130 to dissipate heat from the heat-generating element set 130. Specifically, the first surface S1 of the first heat sink 142 contacts the memory module 134 to dissipate heat from the memory module 134. In some embodiments, the first surface S1 of the first heat sink 142 may also contact elements of the CPU 132 or other elements of the heat-generating element set to dissipate heat therefrom. In the embodiments, the memory module 134 includes at least one memory bank and at least one memory case 134a (shown in FIG. 1). The memory bank is covered by the memory case 134a, and the first surface S1 of the first heat sink 142 contacts the at least one memory case 134a to dissipate heat from the at least one memory case 134a. Specifically, the embodiments depict eight memory cases 134a that can cover at least one memory bank to provide the heat dissipation and dustproof effect for the memory bank. The heat generated by the memory bank may be directed through the memory case 134a to the first heat sink 142 and into the second space IS2. The heat generated by the heat-generating elements of the heat-generating element set 130 may also be directed to the second space IS2 when the first heat sink 142 contacts or is close to the other heat-generating elements of the heat-generating element set 130.

Referring to FIGS. 2 and 7, in the embodiments, the heat dissipating unit 140 further includes a processor heat dissipating unit 148. The processor heat dissipating unit 148 includes a heat conducting seat 148a, a heat conducting pipe 148b, and a heat dissipating module 148c. The heat dissipating module 148c is provided in the second space IS2, and the heat conducting seat 148a and the heat conducting pipe 148b are provided in the first space IS1. Specifically, the heat conducting seat 148a is mounted on the CPU 132, and the heat conducting pipe 148b connects the heat conducting seat 148a and the heat dissipating module 148c. The heat conducting seat 148a may include a base that contacts the CPU 132 and an upper cover. The number of the heat conducting pipes 148b may be one or more, and the base and the upper cover of the heat conducting seat 148a sandwich and fix the heat conducting pipe 148b so that the heat generated by the CPU 132 is conducted into the heat conducting pipe 148b. The heat conducting pipe 148b is filled with a heat conducting gel or a heat conducting liquid to conduct heat to the heat dissipating module 148c. The heat dissipating module 148c includes a plurality of heat dissipating fins to discharge heat to the second space IS2. In the embodiments, the number of the heat dissipating modules 148c is, for example, two, as shown in the drawings. Nonetheless, the number of the heat conducting pipes 148b and the number of the heat dissipating modules 148c may be appropriately configured according to actual requirements.

Referring to FIGS. 2 and 7, in the embodiments, the processor heat dissipating unit 148 further includes a heat dissipating module bottom board 148d, and the heat dissipating module bottom board 148d carries the heat dissipating module 148c. The first opening O1 of the partition 122 accommodates the first heat sink 142 and the heat dissipating module bottom board 148d. Specifically, in the embodiments, the number of the heat dissipating modules 148c is two, and the number of the heat dissipating module bottom boards 148d is also two. Each heat dissipating module bottom board 148d carries a heat dissipating module 148c. The first opening O1 accommodates both the first heat sink 142 and the two heat dissipating module bottom boards 148d. Specifically, the lower board 114, the plurality of sidewalls, the partition 122, the first heat sink 142, and the heat dissipating module bottom boards 148d form the first space IS1.

Referring to FIGS. 4, 5, 7, and 8, the server 100 further includes a network interface card module 200. The network interface card module 200 includes a network interface card 210 located in the first space IS1 and a network interface card carrier board 240, and the network interface card 210 is mounted on the network interface card carrier board 240. Specifically, the network interface card 210 belongs to the heat-generating elements, which is also included in the heat-generating element set 130 described above. The support module 120 further includes a first support 124, and the server 100 further includes a support, i.e., a second support 250. The first support 124 is disposed between the partition 122 and the upper board 112. The second support 250 is disposed between the partition 122 and the lower board 114, and the second support 250 supports the network interface card carrier board 240 above the main board 170.

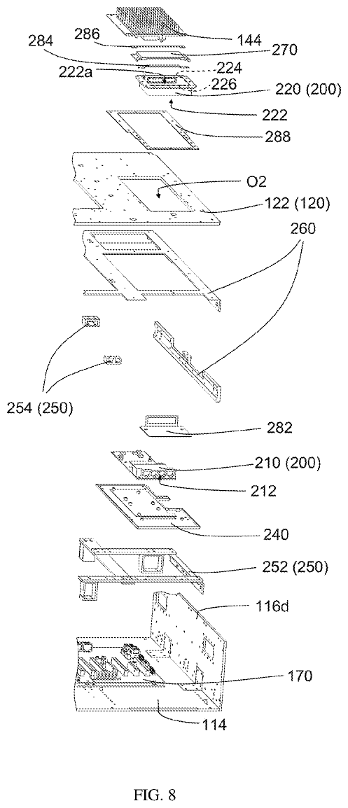

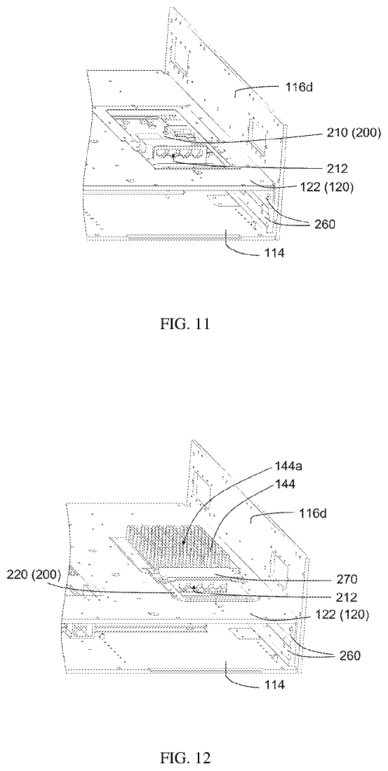

Referring to FIGS. 8 and 11, in the embodiments, the partition 122 further includes an opening (a second opening O2), and the network interface card module 200 further includes a slot body 220 and a network cable (not shown). The second opening O2 accommodates the slot body 220. The slot body 220 includes a recess 222 and a first space opening 224. The recess 222 is recessed toward the first space IS1 to form a recess space 222a, and the first space opening 224 communicates the first space IS1 and the recess space 222a. The slot body 220 further includes a second space opening 226 that communicates the recess space 222a and the second space IS2. The network cable is connected to the network interface card 210. Specifically, the network interface card 210 includes a network port 212 facing the first space opening 224, and the network cable is connected to the network port 212. The network cable sequentially passes through the first space opening 224 and the recess space 222a to enter the second space IS2. In the embodiments, a first end of the network cable is connected to the network interface card 210 and a second end of the network cable is coupled to the main board 170. A second end of the network cable is connected to the first sidewall 116a in the plurality of sidewalls, and the main board 170 is connected to the first sidewall 116a.

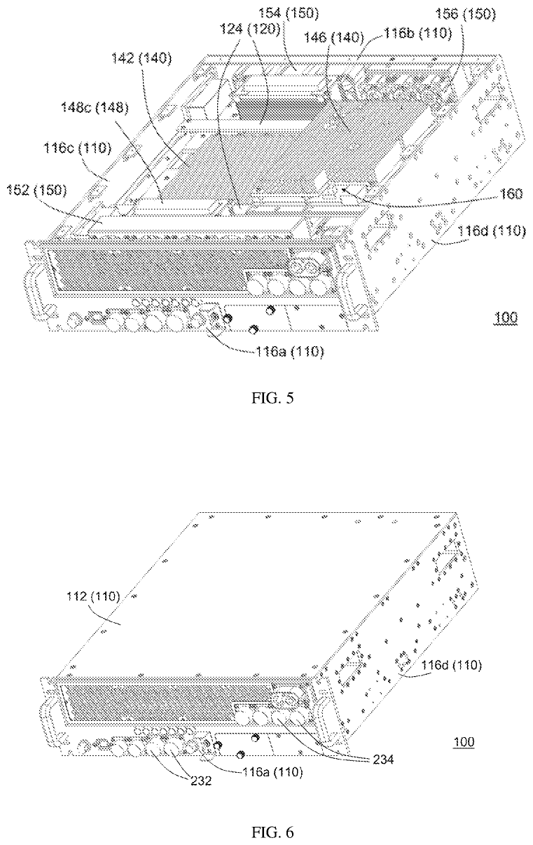

Referring to FIG. 6, the first sidewall 116a serves as the front panel of the server 100, for example, having a first adapter interface 232 corresponding to the first space IS1 and a second adapter interface 234 corresponding to the second space IS2. The second end of the network cable is connected to the second adapter interface 234, and the main board 170 is connected to the first adapter interface 232. In the embodiments, the server 100 further includes an adapter cable outside the housing 110, connecting the first adapter interface 232 and the second adapter interface 234 to realize the coupling relationship between the network interface card and the main board. However, in some embodiments, the network interface card may be coupled to the main board 170 not through the first sidewall 116a. The network interface card may be coupled to the main board 170 through at least one of the first sidewall 116a, the second sidewall 116b, the third sidewall 116c, the fourth sidewall 116d, or the upper board 112. Alternatively, the second end of the network cable may bypass the partition 122 and be coupled to the main board 170 in the first space IS1 in another manner than directly passing through the partition 122, and the present document is not limited thereto.

Referring to FIGS. 8 to 10, in the embodiments, the second support 250 includes the first-layer support 252 and the second-layer support 254. The first-layer support 252 supports the network interface card carrier board 240 above the main board 170, and the second-layer support 254 is stacked on the first-layer support 242 to support the partition 122 above the lower board 114. In addition, the server 100 further includes a partition support 260 positioned between the partition 122 and the lower board 114 and abutting at least one of the plurality of sidewalls, with the partition 122 supported by the partition support 260. Specifically, the partition support 260 includes an elongated portion abutting the fourth sidewall 116d and a board-like portion designed according to the shape of the partition 122. The elongated portion abuts against a corner formed by the lower board 114 and the fourth sidewall 116d, and the board-like portion is connected between the partition 122 and the elongated portion. The second-layer support 254 may, for example, be connected between the partition 122 and the first-layer support 242, and the second-layer support 254 may be in the form of blocks that are centrally disposed in the partition 122 to avoid the problem of cantilevering in the design of the partition 122 or other structures of the server 100's housing 110.

Referring to FIGS. 3, 7 and 8, the heat dissipating unit 140 further includes a heat sink (i.e., a second heat sink 144), and the second opening O2 of the partition 122 accommodates the second heat sink 144. When the second heat sink 144 is installed into the second opening O2, the lower board 114, the plurality of sidewalls, the partition 122, the first heat sink 142, and the second heat sink 144 form the first space IS1. In some embodiments, the heat-generating element set 130 may also include a graphics processing unit (GPU) or a plurality of expansion cards, mounted on the main board 170 or other boards in the first space IS1.

In the embodiments, the second heat sink 144 has a third surface S3 facing the first space IS1 and a fourth surface S4 facing the second space IS2, and the fourth surface S4 of the second heat sink 144 has a heat dissipating structure (i.e., a second heat dissipating structure 144a). In addition, the third surface S3 of the second heat sink 144 contacts the network interface card 210 to dissipate heat from the network interface card 210. The second heat sink 144 may direct the heat generated by the network interface card 210 to the second space IS2. In the embodiments, the second heat dissipating structure 144a is different from the first heat dissipating structure 142a; nonetheless, the second heat dissipating structure 144a may have the same structure as the first heat dissipating structure 142a according to actual requirements.

Referring to FIGS. 8 and 12, in the embodiments, the network interface card module 200 includes a network port partition 270, and the second heat sink 144, the network port partition 270, and the slot body 220 are sequentially arranged and embedded in the second opening O2. Specifically, the position of the second heat sink 144 corresponds to the position of the network interface card 210 to dissipate heat from the network interface card 210. The position of the network port partition 270 corresponds to the position of the network port 212 to cover the network port 212. The slot body 220 is recessed into the first space IS1 to accommodate the network cable and provide a passage for the network cable from the first space IS1 into the second space IS2. Further, referring to FIG. 8, a first cushion 282 is provided between the slot body 220 and the network port 212. A second cushion 284 is provided between the slot body 220 and the network port partition 270. A third cushion 286 is provided between the network port partition 270 and the second heat sink 144. A fourth cushion 288 is provided in an area where the second heat sink 144 contacts the partition 122. In the embodiments, the material of the first cushion 282, the second cushion 284, the third cushion 286, and the fourth cushion 288 is rubber or others. The first cushion 282 contacts the slot body 220 and contacts the network port 212, the second cushion 284 contacts the slot body 220 and contacts the network port partition 270, the third cushion 286 contacts the network port partition 270 and contacts the second heat sink 144, and the fourth cushion 288 contacts the second heat sink 144 and contacts the partition 122. In the contact areas formed by the contacts above, minute voids are sealed by the cushions to achieve the dustproof effect.

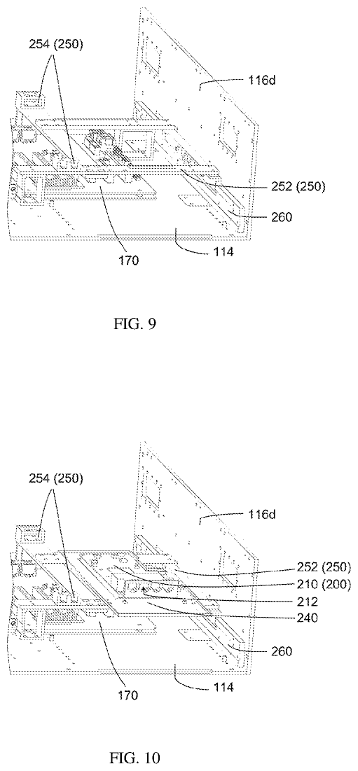

FIGS. 9 to 12 illustrate a process of assembling the network interface card module 200 and related elements thereof according to some embodiments of the present document. First, referring to FIG. 9, the first-layer support 252, the second-layer support 254, and the elongated portion of the partition support 260 are mounted on the main board 170. Next, referring to FIG. 10, the network interface card carrier board 240 and the network interface card 210 are installed. After this, referring to FIG. 11, the board-like portion of the partition support 260, the partition 122, and the fourth cushion 288 are installed. Thereafter, referring to FIG. 12, the first cushion 282, the slot body 220, the second cushion 284, the network port partition 270, the third cushion 286, and the second heat sink 144 are installed. The network cable, not shown in the drawings, may be connected to the network port 212 of the network interface card 210 and enter the second space IS2 above through the slot 220.

Referring to FIGS. 4, 5, and 7, in the embodiments, the server 100 further includes a power module 160 to provide a stable DC power supply for the server 100. The first support 124 supports the power module 160 such that the power module 160 is disposed between the first support 124 and the upper board 112. The heat dissipating unit 140 further includes a third heat sink 146 disposed on the power module 160. Specifically, the power module 160 and the third heat sink 146 are stacked above the second heat sink 144 cooling the network interface card 210, and the first heat sink 142 is disposed on the other side of the second space IS2. An upper space of the housing 110, that is, the second space IS2, includes a first portion IS21 and a second portion IS22 (see FIG. 3). A projection of the first portion IS21 on the upper board 112 does not overlap with a projection of the second portion IS22 on the upper board 112. The first heat sink 142 is within the first portion IS21 of the second space IS2, and the second heat sink 144 and the third heat sink 146 are within the second portion IS22 of the second space IS2.

With continued reference to FIGS. 4, 5, and 7, the server 100 further includes a fan set 150 disposed at a position on the housing 110 corresponding to the second space IS2 so as to dissipate heat from the second space IS2. The fan set 150 includes a first fan set 152, a second fan set 154, and a third fan set 156. The first fan set 152 is disposed on a first sidewall 116a of the plurality of sidewalls, and the second fan set 154 and the third fan set 156 are disposed on a second sidewall 116b of the plurality of sidewalls. Referring to FIGS. 3 and 4, the first fan set 152 corresponds to the first portion IS21 and the second portion IS22 of the second space IS2. Referring to FIGS. 3 and 5, the second fan set 154 corresponds to the first portion IS21 of the second space IS2, and the third fan set 156 corresponds to the second portion IS22 of the second space IS2.

Specifically, the first fan set 152, the second fan set 154, and the third fan set 156 are disposed in the second space IS2 so as to provide an air flow in the second space IS2, thereby discharging heat of the second space IS2 out of the server 100. In this example, the second fan set 154 is positioned adjacent the first heat sink 142 above the CPU 132 and the memory module 134 to dissipate heat from the first heat sink 142. The third fan set 156 is adjacent the second heat sink 144 above the network interface card 210 and the third heat sink 146 above the power module 160 to dissipate heat from the second heat sink 144 and the third heat sink 146. In this example, since there is a distance between the second sidewall 116b and the third heat sink 146, the third fan set 156 may be configured differently from the second fan set 154 in order to improve the heat dissipation efficiency of the third fan set 156. The third fan set 156 extends by a greater distance in the second space IS2 than a distance by which the second fan set 154 extends in the second space IS2. As such, the third fan set 156 is closer to the third heat sink 146 and closer to the second heat sink 144 to achieve better heat dissipation. However, the distance by which the third fan set 156 extends in the second space IS2 may also be set to be less than or equal to the distance by which the second fan set 154 extends in the second space IS2 according to actual requirements, and the present document is not limited thereto. In addition, the number of fans of the first fan set 152, the second fan set 154, and the third fan set 156 may be configured according to actual needs, and more fans may be provided at other locations of the server 100 to achieve a better heat dissipation effect.

In this example, the heat sink (e.g., the first heat sink 142 and the second heat sink 144) and the support module 120 divide the interior space IS into the first space IS1 and the second space IS2, and the heat-generating element set 130 such as the CPU 132 and the memory module 134 are located in the closed first space IS1. The heat sink contacts the heat-generating element set 130 to dissipate heat from the heat-generating element set 130. Accordingly, the heat generated by the operation of the heat-generating element set 130 can be conducted into the second space IS2 through the heat sink, and the heat can be discharged out of the server 100 through the fan set 150 cooling the second space IS2. Since the heat-generating element set 130 such as the CPU 132 and the memory module 134 are located in the closed first space IS1 and are blocked by the support module 120 such as the partition 122, dust generated when the fan set 150 dissipates heat from the second space IS2 does not enter the heat-generating element set 130 in the first space IS1. This enables the prevention of dust from entering the heat-generating element set 130 while efficient dissipation of heat for the server 100 in an in-vehicle operation environment, thereby achieving a more stable operation of the server 100.

In this example, the partition 122 of the support module 120 provides stability to the overall structure of the server 100. The first support 124 supports the overall structure of the housing 110 of the server 100 and also supports the power module 160. The second support 250 supports the network interface card carrier board 240 above the main board 170. Specifically, the main board 170 is also provided with a plurality of supporting mechanisms to support elements and boards above and reduce the possibility of cantilevering the elements. In this example, the housing 110 and the support module 120 allow for various structural designs so that resonance of the server 100 in the in-vehicle vibration environment can be greatly reduced, whereby the server 100 in the in-vehicle operation environment can be more shock-resistant, and a more stable operation of the server 100 is ensured.

Further, in this example, the network cable is connected to the network interface card 210 located in the first space IS1 of the housing 110 of the server 100, and the network cable sequentially passes through the first space opening 224 and the recess space 222a of the slot body 220 to enter the second space IS2 of the housing 110 of the server 100; as a result, even if the network interface card 210 is configured in the first space IS1, the majority of the network cable may be configured in the second space IS2 through the slot body 220, not necessarily configured in the first space IS1 together with the network interface card 210. Therefore, the network interface card 210 may be successfully installed, and adaptation to the server structure design in an in-vehicle environment is realized.

While exemplary embodiments or examples of the present document have been described with reference to the accompanying drawings, it is to be understood that the above exemplary discussion is not intended to be exhaustive or to limit the present document to the precise forms disclosed. Many modifications and variations are possible in light of the above teaching. Accordingly, the disclosed subject matter should not be limited to any single embodiment or example described herein, but rather should be construed in breadth and scope in accordance with the appended claims.

What is claimed is:

1. A server, comprising:
a housing forming an interior space;
a partition dividing the interior space into a first space and a second space, the partition comprising an opening; and
a network interface card module, comprising:
a network interface card located in the first space;
a slot body accommodated by the opening, comprising:
a recess, recessed toward the first space to form a recess space; and
a first space opening communicating the first space and the recess space; and
a network cable connected to the network interface card, the network cable sequentially passing through the first space opening and the recess space to enter the second space.

2. The server according to claim 1, wherein:
the network interface card comprises a network port opened toward the first space, and
the network cable is connected to the network port.

3. The server according to claim 1, further comprising a main board disposed in the first space, wherein:
a first end of the network cable is coupled to the network interface card, and
a second end of the network cable is coupled to the main board.

4. The server according to claim 3, wherein:
the housing comprises an upper board, a lower board, and a plurality of sidewalls;
the lower board, the plurality of sidewalls, and the partition form the first space,
the upper board, the plurality of sidewalls, and the partition form the second space,
the second end of the network cable is connected to a first sidewall among the plurality of sidewalls, and
the main board is connected to the first sidewall.

5. The server according to claim 4, wherein:
the first sidewall has a first adapter interface corresponding to the first space and a second adapter interface corresponding to the second space,
the main board is connected to the first adapter interface,
the second end of the network cable is connected to the second adapter interface, and
the server further comprises an adapter cable outside the housing for connecting the first adapter interface and the second adapter interface.

6. The server according to claim 4, wherein:
the plurality of sidewalls further comprise a second sidewall, a third sidewall, and a fourth sidewall, the second sidewall being opposite the first sidewall, the fourth sidewall being opposite the third sidewall,
the third sidewall, the lower board, and the fourth sidewall form a U-shaped board structure, the first sidewall being a front panel, and the second sidewall being a back panel.

7. The server according to claim 3, wherein the second end of the network cable bypasses the partition and is coupled to the main board in the first space.

8. The server according to claim 3, further comprising a central processing unit and a memory module, wherein the central processing unit and the memory module are mounted on the main board.

9. The server according to claim 3, wherein:
the network interface card module further comprises a network interface card carrier board on which the network interface card is mounted, and
the server further comprises a support supporting the network interface card carrier board above the main board.

10. The server according to claim 9, wherein:
the housing comprises a lower board,
the main board is located on the lower board, and
the support comprises a first support that supports the network interface card carrier board above the main board and a second support that is stacked on the first support to support the partition above the lower board.

11. The server according to claim 1, wherein:
the housing comprises an upper board, a lower board, and a plurality of sidewalls connecting the upper board and the lower board, the partition being positioned between the upper board and the lower board;
the server further comprises a partition support positioned between the partition and the lower board and abutting at least one of the plurality of sidewalls, with the partition being supported by the partition support.

12. The server according to claim 1, further comprising a heat sink accommodated by the opening, wherein:
a surface of the heat sink facing the first space contacts the network interface card to dissipate heat from the network interface card, and
a surface of the heat sink facing the second space has a heat dissipating structure.

13. The server according to claim 12, wherein:
the network interface card module comprises a network port partition, the heat sink, the network port partition, and the slot body being arranged in order and embedded in the opening;
the network interface card comprises a network port opened toward the first space, and a position of the network port partition corresponds to a position of the network port.

14. The server according to claim 13, wherein:
the network cable is connected to the network port,
a first cushion is provided between the slot body and the network port,
a second cushion is provided between the slot body and the network port partition,
a third cushion is provided between the network port partition and the heat sink, and
a fourth cushion is provided at a contact area between the heat sink and the partition.

15. The server according to claim 14, wherein materials of the first, second, third, and fourth cushions are rubber.

16. The server according to claim 1, wherein the server comprises a fan set provided at a position on the housing corresponding to the second space to dissipate heat from the second space.
